(19) United States
(12) Patent Application Publication
(10) Pub. No.: US 2013/0176085 A1
(43) Pub. Date: Jul. 11, 2013

(54) HYBRID BULK ACOUSTIC WAVE RESONATOR

(71) Applicant: Avago Technologies General IP (Singapore) Pte. Ltd., Singapore (SG)

(72) Inventors: Bradley BARBER, Acton, MA (US); Zhiqiang BI, Shrewsbury, MA (US)

(73) Assignee: Avago Technologies General IP (Singapore) Pte. Ltd., Singapore (SG)

(21) Appl. No.: 13/785,104

(22) Filed: Mar. 5, 2013

Related U.S. Application Data
(63) Continuation of application No. 12/624,550, filed on Nov. 24, 2009.

(51) Int. Cl. H03H 9/15

(52) U.S. Cl. CPC H03H 9/15
USPC 333/187

(57) ABSTRACT

A hybrid bulk acoustic wave (BAW) resonator comprises a first electrode, a second. electrode, a piezoelectric layer disposed between the first and second electrodes, and a single mirror pair disposed adjacent the second electrode. In one example, the hybrid bulk acoustic wave resonator further comprises a substrate, and the first electrode is disposed adjacent the substrate. A method of fabricating a hybrid BAW resonator is also disclosed.

### CROSS-REFERENCE TO RELATED APPLICATIONS

The present application is a continuation application under 37 C.F.R. §1.53(b) of U.S. patent application Ser. No. 12/624,550 filed on Nov. 24, 2009, naming Bradley Barber, et al. as inventors. Priority under 35 U.S.C. §120 is claimed from U.S. patent application Ser. No. 12/624,550, and the entire disclosure of U.S. patent application Ser. No. 12/624,550 is specifically incorporated herein by reference.

### BACKGROUND

Bulk acoustic wave (BAW) resonators are used in a variety of electronic devices, for example, to create high performance filters or as resonant elements associated with an integrated circuit (IC) to provide specific electronic functions, such as voltage controlled oscillators or low noise amplifiers. RAW resonators exhibit high performance including relatively low frequency drift with temperature and good power handling, have a small footprint and low profile, and their technology can be made compatible with standard IC technology. As a result, BAW resonators are increasingly used in radio frequency (RF) systems, such as mobile electronic devices and modern wireless communications systems.

A BAW resonator typically includes a layer of piezoelectric material, such as aluminum nitride, sandwiched between upper and lower metal electrodes. When an electric field is applied across the upper and lower electrodes, the structure is mechanically deformed due to the inverse piezoelectric effect and an acoustic wave is launched into the structure. The wave propagates parallel to the applied electric field and is reflected at the electrode/air interfaces.

FIG. 1 illustrates one example of a BAW resonator structure referred to as a thin film bulk acoustic resonator (FBAR). As discussed above, the resonator includes a piezoelectric layer 110 disposed between an upper electrode 120 and a lower electrode 130, In the FBAR type of resonator, air interfaces are required on either side of the vibrating resonator. Accordingly, the vibrating part of the structure is either suspended over a substrate 140 and manufactured on top of sacrificial layer (which is then removed), or supported around its perimeter (as shown in FIG. 1) and realized by etching part of the substrate 140 away. The substrate is typically silicon, although other substrate materials can be used.

Referring to FIG. 2, there is illustrated a second type of piezoelectric resonator known as a solidly mounted resonator (SMR). In the SMR structure, the lower electrode is mounted above an acoustic mirror stack 210 comprising multiple reflective layers each approximately one quarter-wavelength thick at the acoustic wavelength. The mirror stack 210 comprising alternating layers of low and high acoustic impedance (acoustic impedance is the product of acoustic speed and material density) materials, for example, low density silicon dioxide and a high density metal, such as Tungsten. The mirror stack 210 replaces the air interface below the lower electrode 130 in the FBAR structure, and provides isolation between the resonator and the silicon substrate 140, preventing acoustic losses into the substrate.

### SUMMARY

According to a representative embodiment, acoustic wave resonator comprises: a substrate; a first electrode supported by the substrate; a piezoelectric layer formed on the first electrode; a second electrode formed on the piezoelectric layer; a pair of low and high impedance layers formed in contact with one of the first and second electrodes; and a passivation layer formed on the second electrode if the pair of low and high impedance layers is in contact with the first electrode, or on the pair of low and high impedance layers if the pair of low and high impedance layers is in contact with the second electrode.

According to another representative embodiment, an acoustic wave resonator comprises: a substrate; a first electrode supported by the substrate; a piezoelectric layer formed on the first electrode; a second electrode formed on the piezoelectric layer; and a passivation layer formed on the second electrode, wherein at least one of the first and second electrodes comprises a pair of low and high impedance layers.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. Any embodiment disclosed herein may be combined with any other embodiment in any manner consistent with at least one of the objects, aims, and needs disclosed herein, and references to “an embodiment,” “some embodiments,” “an alternate embodiment,” “various embodiments,” “a representative embodiment” or the like are not necessarily mutually exclusive and are intended to indicate that a particular feature, structure, or characteristic described in connection with the embodiment may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. Where technical features in the figures, detailed description or any claim are followed by references signs, the reference signs have been included for the sole purpose of increasing the intelligibility of the figures, detailed description, and/or claims. Accordingly, neither the reference signs nor their absence are intended to have any limiting effect on the scope of any claim elements. In the figures, each identical or nearly identical component that is illustrated in various figures is represented by a like numeral. For purposes of clarity, not every component may be labeled in every figure. In the figures:

FIG. 1 is a cross-sectional view of one example of a known thin film bulk acoustic resonator;

FIG. 2 is a cross-sectional view of one example of a known solidly mounted resonator;

FIG. 3 is a cross-sectional view of a hybrid bulk acoustic wave resonator according to a representative embodiment;

FIG. 4 is a plot of the electrical impedance as a function of frequency for a bulk acoustic wave resonator according to a representative embodiment;

FIG. 5A is a cross-sectional view of a bulk acoustic wave resonator including a mode control structure according to a representative embodiment;

FIG. 5B is a cross-sectional view of a bulk acoustic wave resonator including a mode control structure according to a representative embodiment;

FIG. 6 is a plot of the electrical impedance as a function of frequency for examples of bulk acoustic wave resonators according to a representative embodiment;

FIG. 7A is a cross-sectional view of a hybrid BAW resonator according to a representative embodiment;

FIG. 7B is a cross-sectional view of a hybrid RAW resonator according to a representative embodiment;

FIG. 8 is a flow diagram illustrating a method of manufacture of a hybrid BAW resonator according to a representative embodiment; and

FIG. 9 is a flow diagram illustrating a method of manufacture of a hybrid BAW resonator including a mode control structure according to a representative embodiment.

### DEFINED TERMINOLOGY

The terms ‘a’ or ‘an’, as used herein are defined as one or more than one.

The term ‘plurality’ as used herein is defined as two or more than two.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

### DETAILED DESCRIPTION

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the illustrative embodiments. Such methods and apparati are clearly within the scope of the present teachings.

Representative embodiments are directed to a hybrid BAW resonator structure that provides advantages over known BAW resonators. According to a representative embodiment, the hybrid BAW resonator comprises an FBAR coupled to an acoustic mirror pair, as discussed in more detail below. The addition of the acoustic mirror pair may significantly alter the dispersion of the resonator and allow reduction in, or elimination of, the losses below the resonant frequency. In addition, the hybrid BAW structure may have significantly better frequency trimming tolerance than known FBAR structures, allowing manufacture of a high frequency, high coupling filter, as discussed further below. Certain aspects of the hybrid BAW resonators of representative embodiments may be fabricated according to the teachings of commonly owned U.S. Pat. Nos. 5,587,620; 5,873,153; 6,384,697; 6,507,983; and 7,275,292 to Ruby, et at; and U.S. Pat. No. 6,828,713 to Bradley, et. al. The disclosures of these patents are specifically incorporated herein by reference. It is emphasized that the methods and materials described in these patents are representative and other methods of fabrication and materials within the purview of one of ordinary skill in the art are contemplated. Moreover, when connected in a selected topology, a plurality of acoustic resonators 100 can function as an electrical filter. For example, the acoustic resonators 100 may be arranged in a ladder-filter arrangement, such as described in U.S. Pat. No. 5,910,756 to Ella, and U.S. Pat. No. 6,262,637 to Bradley, et al., the disclosures of which are specifically incorporated herein by reference. The electrical filters may be used in a number of applications, such as in duplexers.

It is to be appreciated that embodiments of the methods and apparatus discussed herein are not limited application to the details of construction and the arrangement of components set forth in the following description or illustrated in the accompanying figures. The methods and apparatus are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments.

Also, the phraseology and terminology used herein is for the purpose of description and should not be regarded as limiting. Any references to embodiments or elements or acts of the systems and methods herein referred to in the singular may also embrace embodiments including a plurality of these elements, and any references in plural to any embodiment or element or act herein may also embrace embodiments including only a single element. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, and upper and lower are intended for convenience of description, not to limit the present systems and methods or their components to any one positional or spatial orientation.

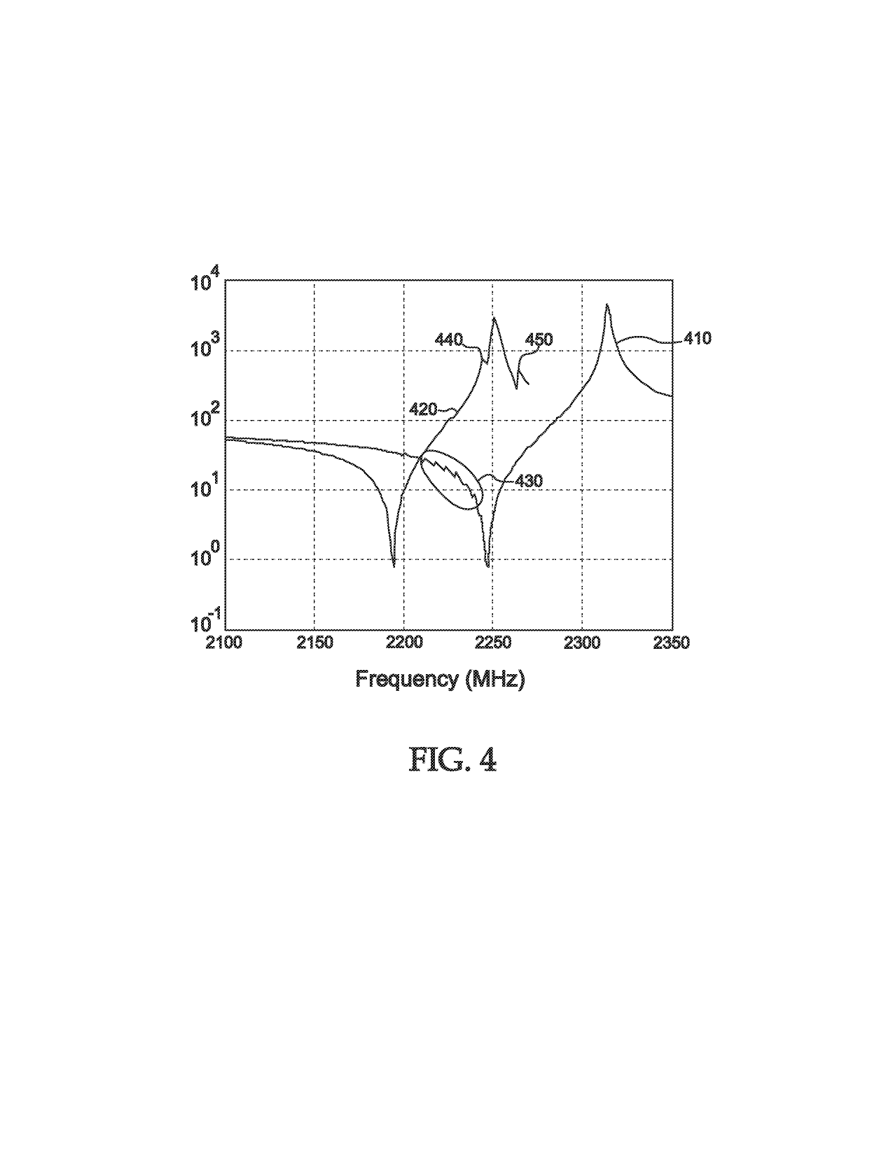

Referring to FIG. 3, there is illustrated a diagram of one example of a hybrid BAW resonator 300 according to a representative embodiment. The BAW resonator comprises a piezoelectric layer 310 disposed between a first electrode 320 and a second electrode 330. The second electrode 330 is disposed adjacent an acoustic mirror pair 340 which comprises a low acoustic impedance mirror layer 350 typically constructed of, for example, silicon dioxide, and a high acoustic impedance layer 360 typically constructed of, for example, a high density metal. In a representative embodiment, the hybrid BAW resonator 300 comprises only the single acoustic mirror pair 340. In other examples, additional acoustic mirror layers may be added, The hybrid BAW resonator 300 may be coupled to a. substrate (not shown), for example, a silicon substrate or other high-resistivity substrate, or may be separated from the substrate by fabrication using a. sacrificial layer as with FBAR structures.

In one example, the piezoelectric layer 310 comprises Aluminum nitride (AIN). In other examples, other piezoelectric materials such as, for example, Zinc oxide (ZnO) or pzT may be used; however, Aluminum nitride may be presently preferred in some embodiments due to its excellent chemical, electrical and mechanical properties, particularly if the resonator is to be integrated with other integrated circuits on the same wafer, The first and second electrodes 320, 330 comprise metal, for example, a high density metal such as tungsten or molybdenum. In one example, the low acoustic impedance mirror layer 350 comprises silicon dioxide. In one example, the high acoustic impedance layer 360 comprises tungsten. Those skilled in the art will appreciate, however, given the benefit of this disclosure, that other suitable materials may be used for any of the layers discussed herein.

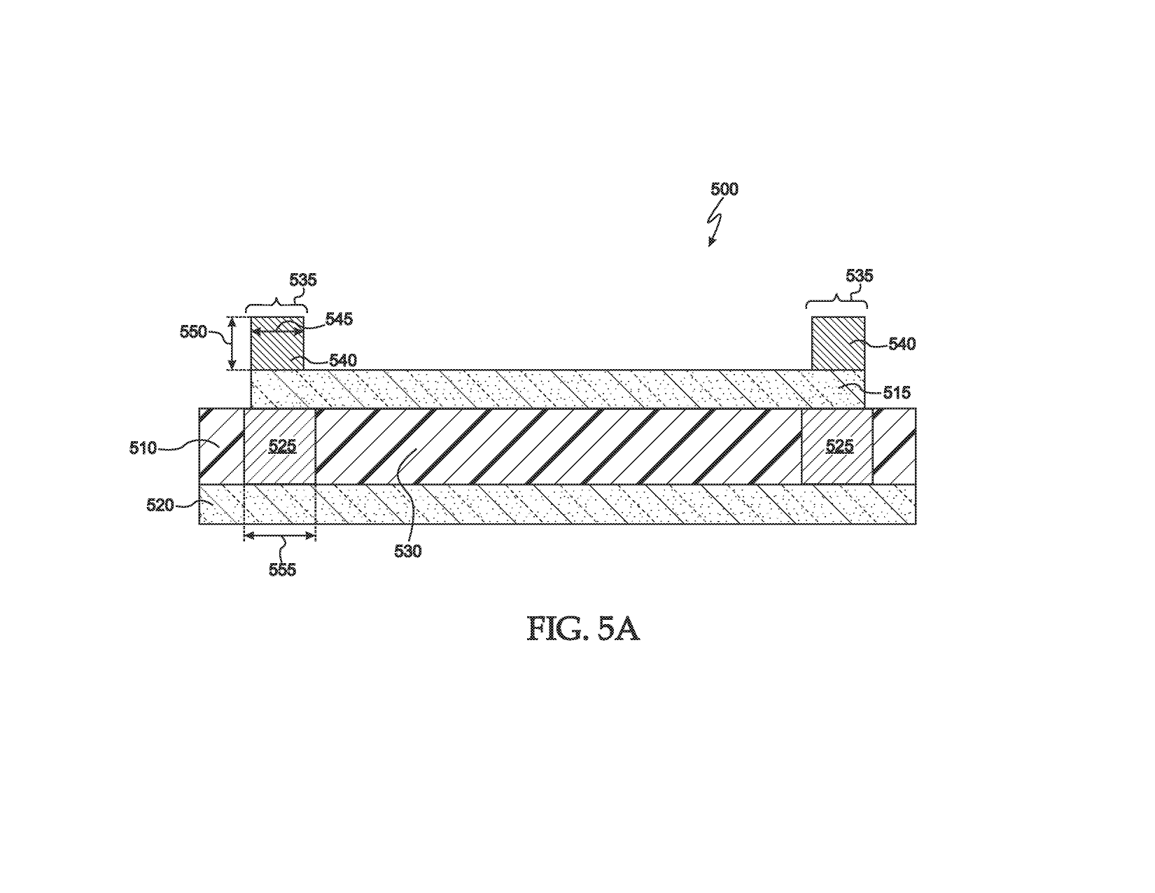

Referring to FIG. 4, there is illustrated a plot of the electrical impedance as a function of frequency for each of a known FBAR resonator and an illustrative hybrid BAW resonator according to a representative embodiment. Trace 410 represents a known FBAR structure, and trace 420 represents an example of the hybrid BAW structure according to a representative embodiment. As can be seen in FIG. 4, the known FBAR has losses below the resonant frequency 460, demonstrated by the significant ripple in trace 410, for example in region 430. By contrast, trace 420 is relatively smooth at frequencies below the resonant frequency 470, demonstrating that the hybrid BAW structure has less loss at these frequencies. As can be seen in FIG. 4, in one example, the hybrid BAW structure does have loss at high frequencies above the resonant frequency, as indicated by ripples 440 and 450. Thus, according to a representative embodiment, mode control techniques may be applied to “engineer” the loss to particular frequencies that are preferably well outside of the operating range of the device in which the resonator is to be used.

As discussed above, when an electric field is applied across the two electrodes of the BAW resonator, the electric field causes the layer of piezoelectric material to vibrate. As a result, the piezoelectric material can generate a number of allowed modes of acoustic wave propagation, which include the desired longitudinal mode. However, unwanted excitation of energy in modes of wave propagation that have high energy loss, such as lateral modes, can cause a significant loss of energy in a BAW resonator and, thereby, undesirably lower the BAW resonator's quality factor (Q) at some frequencies. The Q a resonator can be defined as ratio of the resonance frequency v₀ and the full width at half-maximum (FWHM) bandwidth δv of the resonance:

$$Q = \frac{{v}_{0}}{δ v}$$

Accordingly, in a representative embodiment, a mode control technique may be applied to reduce the amount of energy that is excited in unwanted modes of propagation and thereby reduce loss.

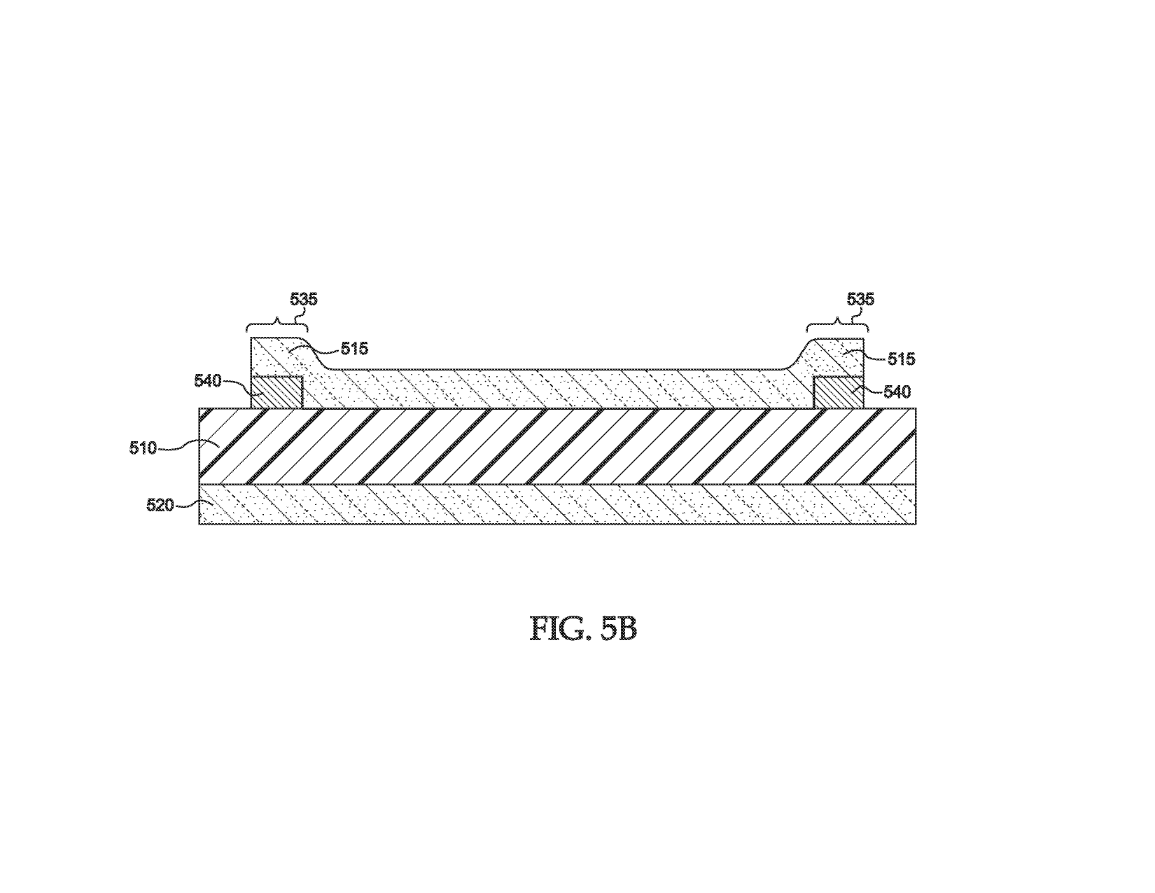

Referring to FIG. 5A, there is illustrated in cross-section one example of a BAW resonator 500 including a mode control structure in accordance with a representative embodiment. The BAW resonator 500 includes a piezoelectric layer 510 disposed between upper and lower electrodes 515, 520, respectively. The BAW resonator 500 also includes a controlled thickness region 535. In one example, the mode control structure includes a material segment 540 disposed in the controlled thickness region 535, as shown in FIG. 5A. The material segment 540 is situated over the upper electrode 515 at the edge of BAW resonator 500 in the controlled thickness region 535 and may extend along the entire perimeter of BAW resonator. The material segment 540 provides thickness shaping at the edge of the BAW resonator 500. The material segment 540 may comprise, for example, a metal, such as a low or high density metal, a dielectric material, or a semiconductor material, The material segment 540 causes reduced electromagnetic coupling in the controlled thickness region 535, thereby providing mode control, as discussed further below.

Still referring to FIG. 5A, in the illustrated example, the piezoelectric layer 510 includes a disrupted texture region 525 and non-disrupted texture region 530. In a representative embodiment, the disrupted texture region and material segment 540 together form one example of a mode control structure. Alternatively, however, the mode control structure may comprise the material segment 540 without the disrupted texture region 525. In the illustrated example, the disrupted texture region 525 is situated in controlled thickness region 535 at the edge of the BAW resonator 500 and extends along the entire perimeter of the BAW resonator. In the disrupted texture region 525, the crystallinity of the piezoelectric material is disrupted so as to cause significantly reduced electromechanical coupling therein. The non-disrupted texture region 530 is situated adjacent to and surrounded by the disrupted texture region 525. The non-disrupted texture region 530 comprises piezoelectric material having a crystallinity that has not been intentionally disrupted.

There are several methods by which the disrupted texture region 525 may be formed. In one example, prior to formation of the piezoelectric layer 510, the surface area that will underlie disrupted texture region 525 can be sufficiently disturbed so as to ensure that the texture of the piezoelectric material will be disrupted when piezoelectric layer 510 is formed. For example, a thin layer of material known to disrupt texture, such as silicon oxide, can be deposited over a thin seed layer (not shown in FIG. 5A) in the surface region of lower electrode 520 over which the disrupted texture region 525 will be formed. As another example, an etch process or other suitable process can be utilized to roughen the surface region of lower electrode 520 over which disrupted texture region 525 will be formed. In another example, the surface region of a layer (not shown in FIG. 5A) underlying the region of the lower electrode 520 over which disrupted texture region 525 will be formed can be roughened prior to forming the lower electrode. The resulting disruption in the texture of the lower electrode 520 caused by the roughening of the surface region of the underlying layer can, in turn, cause the texture of the piezoelectric material to be disrupted in disrupted texture region 525 when piezoelectric layer 510 is formed.

In the example illustrated in FIG. 5A, the material segment 540 is disposed over the upper electrode 515. In another example, the material segment 540 may be disposed between the upper electrode 515 and the piezoelectric layer 510 in the controlled thickness region 535, as shown in FIG. 5B. In this example, the material segment 540 may provide a similar result as is achieved by using the disrupted texture region 525 discussed above. The material segment 540 again may comprise, for example, a dielectric material, such as silicon oxide or silicon nitride, or a low density metal such as titanium or aluminum.

As a result of the mode control structure in the controlled thickness region 535, the electromechanical coupling can be controlled and, thereby, significantly reduced in the controlled thickness region 535. Thus, electromechanical coupling into unwanted modes, such as lateral modes, can be significantly reduced in the controlled thickness region 535. Coupling into the desired longitudinal mode may also be reduced in the controlled thickness region 535. However, the overall loss of coupling into the longitudinal mode in BAW resonator 500 as a result of the loss of coupling in controlled thickness region 535 is significantly less than the overall reduction in energy loss achieved in BAW resonator 500 by reducing electromechanical coupling into unwanted modes in the controlled thickness region 535. Also, the width 545, thickness 550, the composition of material segment 540, and width 555 of the disrupted texture region 525 of the piezoelectric layer 510 can be appropriately selected to optimize reduction of coupling into unwanted modes, such as lateral modes.

Thus, by utilizing the material segment 540 and optionally the disrupted texture region 525 of the piezoelectric layer 510 to reduce electromechanical coupling in the controlled thickness region 535, embodiments of the BAW resonator 500 may achieve a significant reduction of electromechanical coupling into unwanted modes, thereby significantly reducing overall energy loss in BAW resonator 500. By reducing overall energy loss, embodiments of the BAW resonator 500 may advantageously achieve an increased Q. Further examples of loss control structures and techniques are discussed in U.S. application Ser. No. 12/150,244entitled “BULK ACOUSTIC WAVE RESONATOR WITH REDUCED ENERGY LOSS,” filed on Apr. 24, 2008, and in U.S. application Ser. No. 12/150,240 entitled “BULK ACOUSTIC WAVE RESONATOR WITH CONTROLLED THICKNESS REGION HAVING CONTROLLED ELECTROMECHANICAL COUPLING,” filed on Apr. 24, 2008, the disclosures of which are specifically incorporated herein by reference in their entireties.

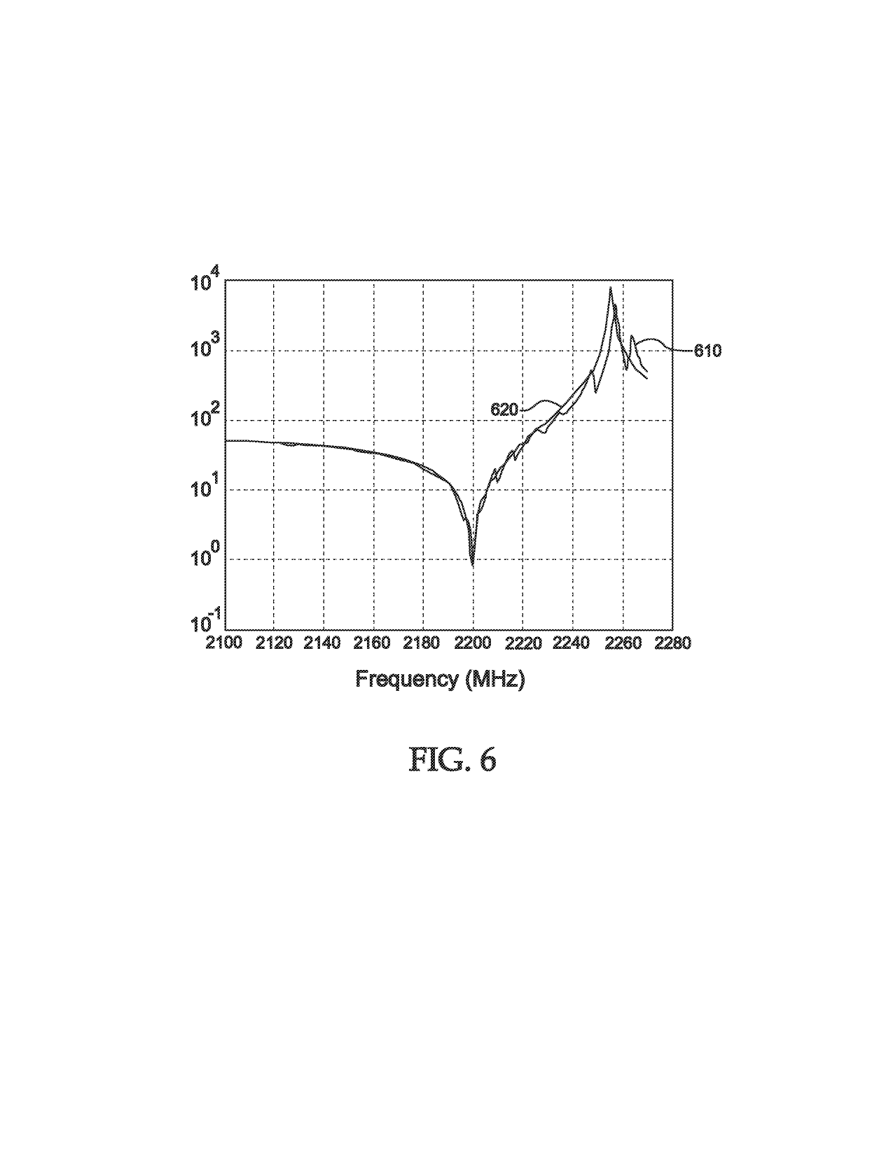

Referring to FIG. 6, there is illustrated an example of improved performance achieved using mode control techniques according to a representative embodiment. FIG. 6 is a graph of the electrical impedance as a function of frequency for an example of each of a hybrid BAW resonator without mode control and one with mode control. Trace 610 represents an example hybrid BAW resonator that does not include a mode control structure. As can be seen in FIG. 6, the resonator has significant loss at frequencies above the resonant frequency f_{R}. Trace 620 represents an example hybrid BAW resonator that incorporates a mode control structure, as discussed above. As can be seen in FIG. 6, trace 620 is significantly smoother than trace 610. Thus, the mode control structure facilitates reducing loss at the frequencies above the resonant frequency.

Hybrid BAW resonator structures according to aspects and embodiments may also allow practical, cost-effective manufacture of a high-frequency resonator, for example, having a resonant frequency of several gigahertz. As discussed above, BAW resonators may comprise a multi-layer film stack, the thickness of which may determine the resonant frequency. During BAW resonator manufacture, there can be a wide distribution of resulting resonant frequencies after initial wafer processing due to non-uniformity of film deposition, which can adversely affect device yield. As a result, a wafer trimming process typically may be used in which a determined amount of material is removed from the top layer of the multi-film stack to achieve a target resonant frequency. The top layer is initially deposited more thickly than desired, resulting in a resonant frequency below the desired resonant frequency, then a determined thickness of the layer is removed to tune the frequency higher to the desired value. One example of a wafer trimming method, also referred to as frequency trimming, is discussed in U.S. Patent Application Publication 20100068831 entitled “METHOD FOR WAFER TRIMMING FOR INCREASED DEVICE YIELD” and filed on Sep. 12, 2008, the disclosure of which is specifically incorporated herein by reference in its entirety.

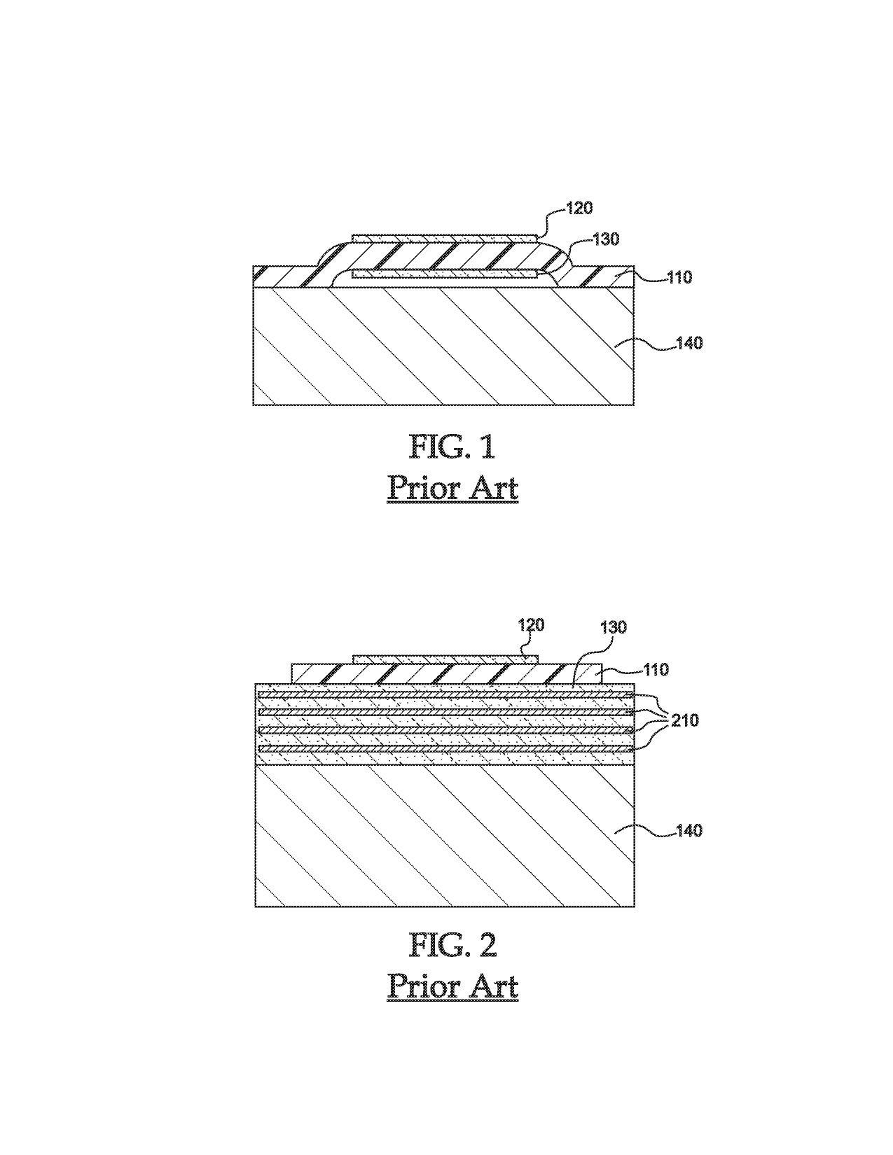

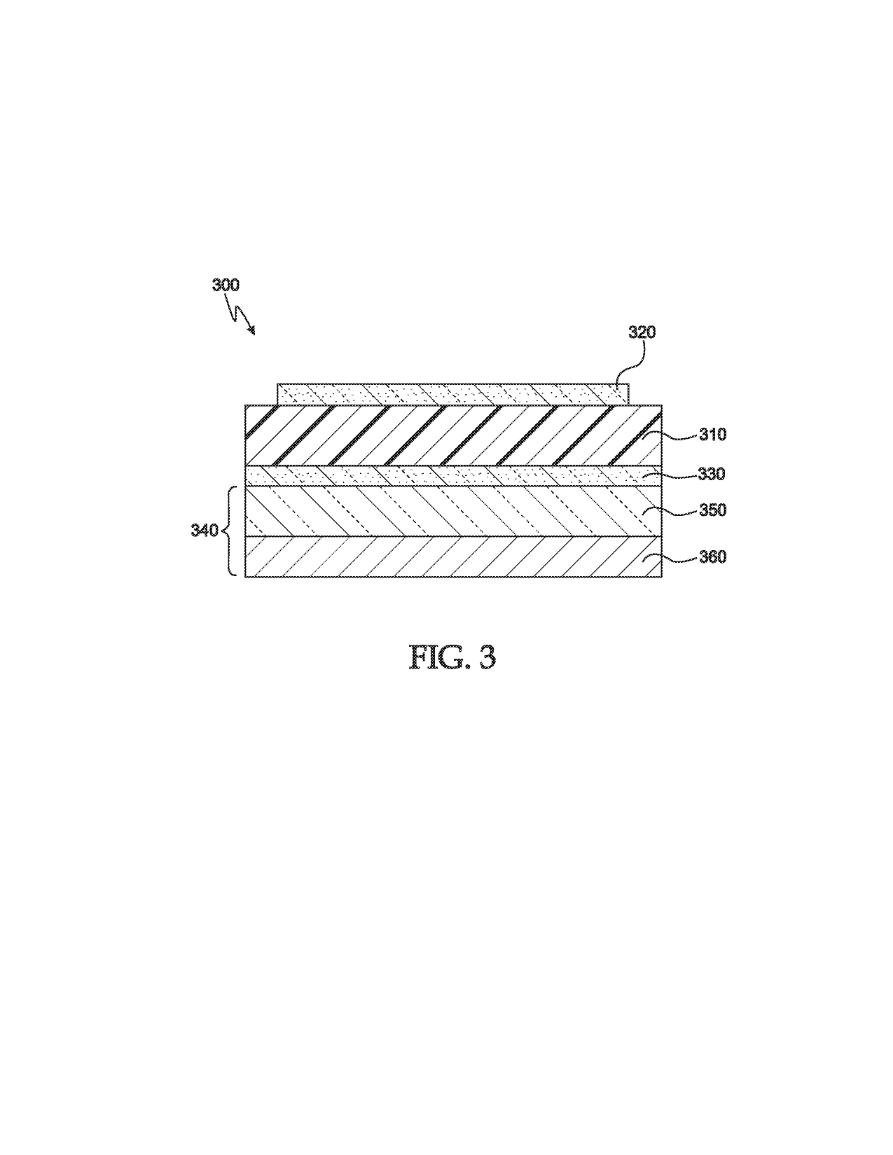

The thickness of the material removed from the top layer (e.g., top electrode or film layer disposed over the top electrode) of the resonator during the wafer trimming process determines the degree of frequency tuning. The thickness of material that must be removed to tune the resonant frequency by a certain amount depends, at least in part, on the desired resonant frequency. For example, for a resonator with a desired center resonant frequency of 5 Ghz (also referred to as 5 GHz resonator), having a known FBAR or SMR structure, as shown in FIGS. 1 and 2, about 2.8 Angstroms (Å) of material is typically removed from the upper electrode 120 to increase the center resonant frequency by 1 MHz. One Angstrom is the thickness of one atomic layer of material. Thus, at high frequencies, accurate frequency trimming is very difficult.

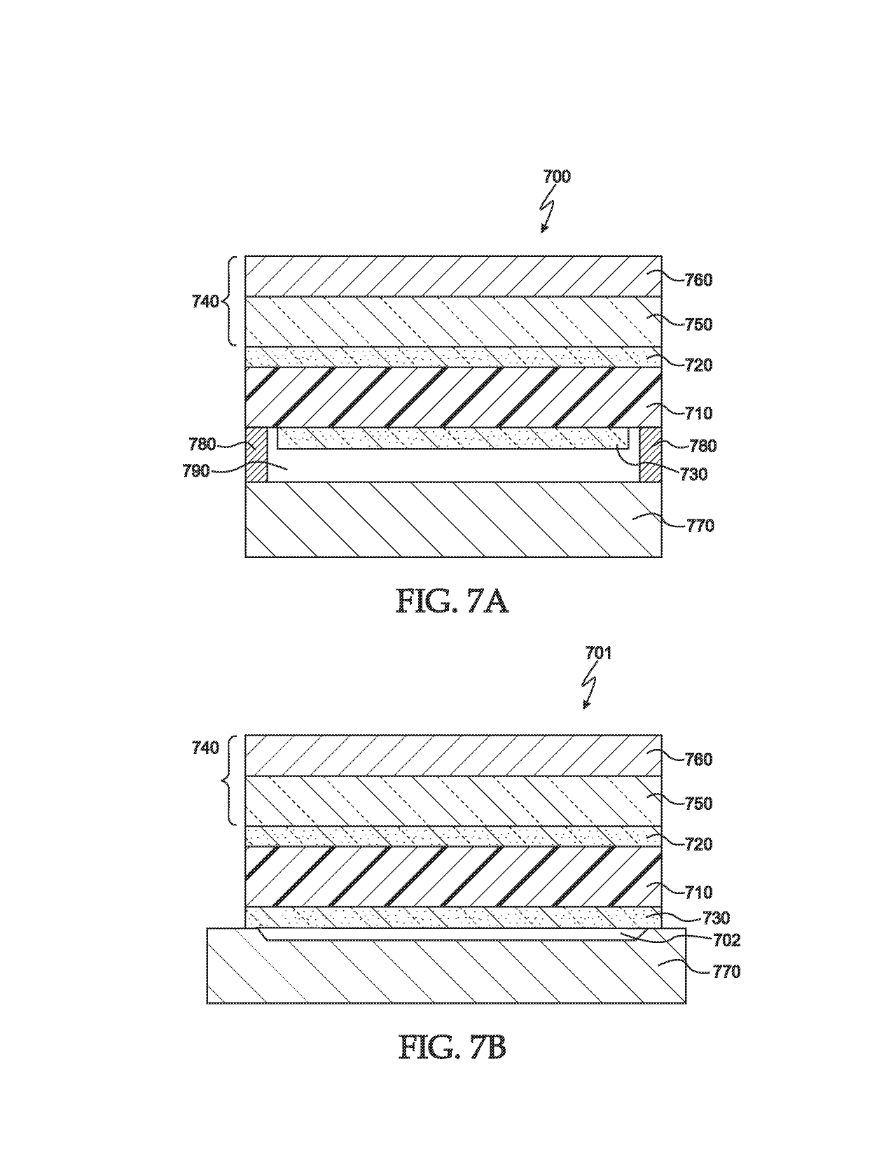

According to a representative embodiment, a hybrid BAW resonator includes a top mirror pair such that the frequency trimming process may be applied to a mirror layer, rather than the top electrode or a thin passivation layer in contact with the top electrode, as discussed further below. FIG. 7A illustrates in cross-section an example of hybrid BAW resonator according to a representative embodiment. In the illustrated example, the hybrid BAW acoustic resonator 700 includes a piezoelectric layer 710 sandwiched between an upper electrode 720 and a lower electrode 730. A mirror pair 740 comprising a low acoustic impedance mirror layer 750 and a high acoustic impedance mirror layer 760. In one example, the hybrid BAW acoustic resonator 700 is substantially identical to the hybrid BAW structure discussed above with reference to FIG. 3, only is manufactured “upside-down,” such that the lower electrode 730, rather than the mirror pair 740, is proximate the substrate 770. A cavity 790 may be provided between the lower electrode 730 and the substrate 770 by supports 780. In one example, these supports 780 may be extensions of the piezoelectric layer 710, as discussed above with reference to FIG. 1.

Providing the mirror pair 740 as the top layers of the resonator structure may offer several advantages, including significantly easing the frequency trimming process. In particular, providing a top mirror and trimming the mirror rather than the upper electrode (e.g., first electrode 320) significantly reduces the sensitivity of the resonator to frequency trimming, making it easier to accurately trim the device to a desired resonant frequency. This reduced sensitivity due to the presence of the top mirror results because, due to the acoustic reflections performed by the mirror pair, there is less acoustic energy at the top of the structure where frequency trimming occurs and therefore removal of the material has a reduced impact on the frequency. In addition, as the desired resonant frequency of the resonator increases, the film layers (e.g., the upper and lower electrodes and piezoelectric layer, as well as an optional upper film over the upper electrode) are made thinner to achieve the high resonant frequency. As a result, trimming these thin films becomes extremely difficult because the amount of material to be removed to achieve a desired change in frequency is very small. For example, as discussed above, at 5 GHz, the tuning sensitivity of a resonator without atop mirror is about 2.8 Å/MHz. By contrast, if the trimming is performed on the top mirror, e.g., on high acoustic impedance minor layer 760, the frequency sensitivity of the resonator to is substantially reduced. For example, in one example of a hybrid BAW resonator including the minor pair 740, as illustrated in FIG. 7, the tuning sensitivity of the resonator is about 83 Å/MHz. Including the top mirror may cause a slight reduction in the bandwidth of the resonator, but this is offset by the improved ability to tailor the resonant frequency. In one example, the fractional separation in frequency between the minimum and maximum impedances for a hybrid BAW resonator including atop mirror was calculated to be about 2.31%, compared to about 2.6% for a similar resonator without a top mirror. Furthermore, in accordance with a representative embodiment, a trimming layer 765 of comparatively low acoustic impedance material may be provided over the mirror pair 740, and specifically over high acoustic impedance mirror layer 760. Illustratively, the trimming layer 765 of comparatively low acoustic impedance material disposed over the mirror pair 740 may be AIN. This trimming layer 765 of comparatively low acoustic impedance material is provided to foster trimming the hybrid BAW acoustic resonator 700 as described herein.

In a representative embodiment, a BAW resonator structure may include both a top and bottom mirror. For example, a BAW resonator structure may include a known SMR structure, such as illustrated in FIG. 2, with an additional top mirror added above the upper electrode 120. In another example, a hybrid BAW resonator such as that illustrated in FIG. 3 may further include a second mirror pair (not shown) adjacent the first electrode 320. However, including both a top and bottom mirror may significantly reduce the coupling, rendering the device impractical for some applications. Accordingly, it may be presently preferred to use a hybrid BAW structure such as shown in FIG. 7A, which includes FBAR-like electrode-piezoelectric-electrode “sandwich” for good coupling, and the mirror pair 740 for improved manufacturability at high frequencies due to the decreased frequency tuning sensitivity.

Referring to FIG. 7B there is illustrated in cross-section an example of hybrid BAW resonator 701 according to a representative embodiment. In the illustrated example, the hybrid BAW resonator 701 comprises piezoelectric layer 710 sandwiched between the upper electrode 720 and the lower electrode 730. Mirror pair 740 comprises low acoustic impedance minor layer 750 and high acoustic impedance mirror layer 760. In one example, the hybrid BAW acoustic resonator 700 is substantially identical to the hybrid BAW structure discussed above with reference to FIG. 3, only is manufactured “upside-down,” such that the lower electrode 730, rather than the mirror pair 740, is proximate the substrate 770. A cavity 702 is provided in the substrate 770 beneath the lower electrode 730. The cavity 702 maybe formed by a number of known methods, for example as described in U.S. Pat. No. 6,384,697 to Ruby, et al., the disclosure of which is specifically incorporated herein by reference, Thus, in the present embodiment, the hybrid HAW resonator 701 comprises minor pair 740 disposed over one electrode (e.g., upper electrode 720) and cavity 702 beneath the other electrode (e.g., lower electrode 730).

Many of the details of the hybrid BAW resonator 701 are common to the hybrid BAW acoustic resonator 700 described in connection with the representative embodiments of FIG. 7A. However, and as will be appreciated from a review of FIG. 7B, the cavity 702 is provided in the substrate 770, rather than between the substrate 770 and the lower electrode 730. As such, many of the common details of the hybrid BAW acoustic resonator 700 are not repeated in the description of the representative embodiments of FIG. 7B.

As described above in connection with the hybrid BAW acoustic resonator 700, providing the mirror pair 740 as the top layers of the resonator structure may offer several advantages, including significantly easing the frequency trimming process. Furthermore, in accordance with a representative embodiment, trimming layer 765 of comparatively low acoustic impedance material may be provided over the mirror pair 740, and specifically over high acoustic impedance mirror layer 760. Illustratively, the trimming layer 765 of material disposed over the mirror pair 740 may be AIN. This trimming layer 765 of comparatively low acoustic impedance material is provided to foster trimming the hybrid BAW acoustic resonator 700 as described herein.

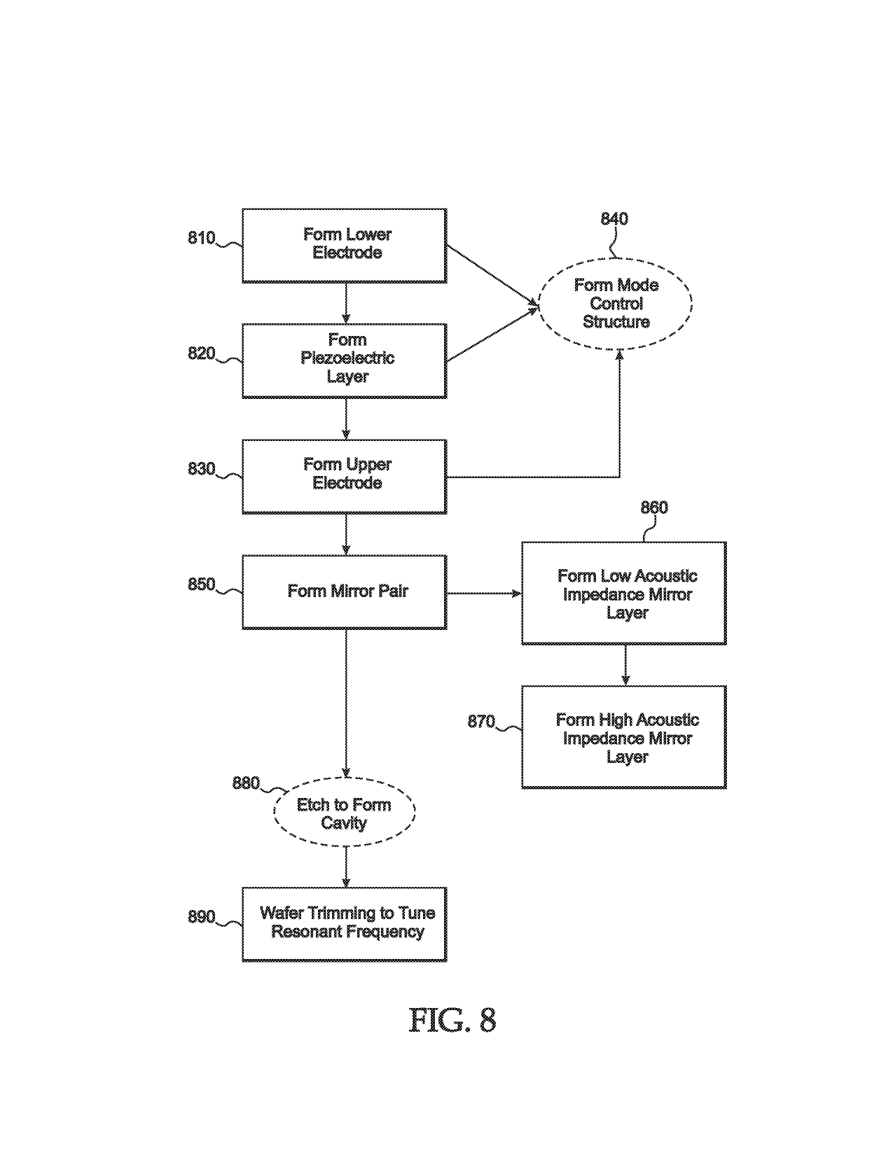

Referring to FIG. 8, there is illustrated a flow diagram of one example of a method of manufacture of a hybrid BAW resonator according to a representative embodiment. In step 810, the lower electrode 730 may be formed on the substrate 770. The lower electrode 730 (or 520 in FIGS. 5A and 5B) can be formed by depositing on the substrate 770, or on a sacrificial layer (not shown), a layer of high density metal, such as tungsten or molybdenum using, for example, a physical vapor deposition (PVD) or sputtering process, or other suitable deposition process, and appropriately patterning the layer of high density metal. The piezoelectric layer 710 (or 510) may then be formed over the lower electrode 730 (or 520), in step 820. The piezoelectric layer 710 (or 510) may comprise, for example, aluminum nitride (AIN) or other suitable piezoelectric material. The piezoelectric layer 710 (or 510) can be formed by, for example, depositing a layer of aluminum nitride over the lower electrode 730 (or 520) using a PVD or sputtering process, a chemical vapor deposition (CVD) process, or other suitable deposition process. The upper electrode 720 (or 515) may then be formed above the piezoelectric layer 710 (or 510) in step 830. Similar to step 810, step 830 may include depositing and optionally appropriately patterning a layer of high density metal such as, for example, tungsten or molybdenum to form the upper electrode 720 (or 515).

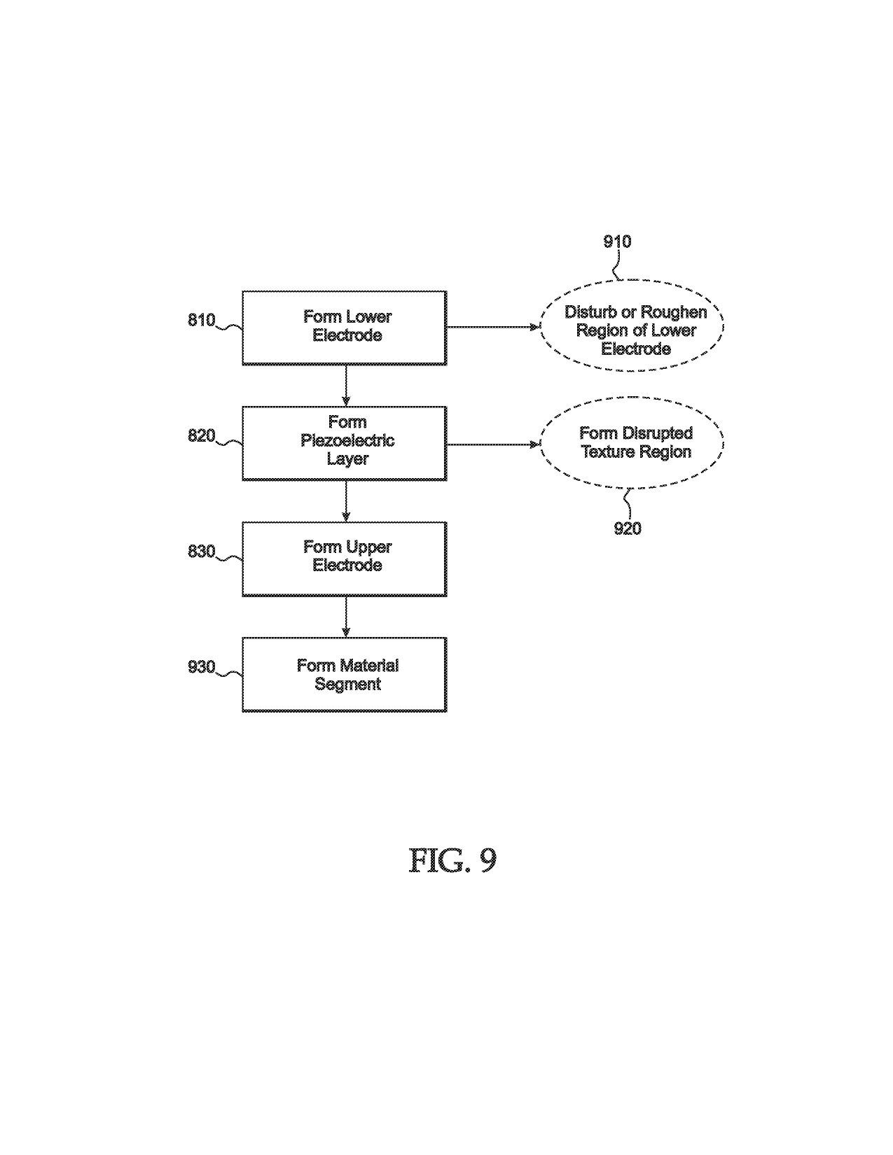

As discussed above, in a representative embodiment the hybrid BAW resonator includes a mode control structure to control and/or reduce loss. Thus, the method may optionally include a step 840 of forming the mode control structure. Referring to FIG. 9, in a representative embodiment in which the mode control structure includes a disrupted texture region, the step 810 of forming the lower electrode 520 (see FIG. 5) may include disrupting or roughening a portion of the lower electrode 520 (step 910), such that the step 820 of forming the piezoelectric layer 510 includes forming a disrupted texture region 525 (step 920), as discussed above. In another example, the mode control structure includes a material segment 540 and thus the method further includes forming the material segment 540. As discussed above, in one example, the material segment 540 is disposed above the upper electrode 515. Accordingly, the method may include a step 930 of forming the material segment 540 over the upper electrode 515.

Alternatively, as also discussed above, the material segment 540 may be formed between the piezoelectric layer 510 and the upper electrode 515, in which case, step 930 may be performed prior to step 830 and may include forming the material segment 540 over the piezoelectric layer 510 to obtain a structure such as that shown in FIG. 5B. The material segment 540 can be formed by depositing a layer of material over the upper electrode 515 or piezoelectric layer 510 using, for example, a PVD or sputtering process, a CVD process, or other suitable deposition process. Step 930 may also include appropriately patterning the layer of material using a suitable etch process to form the inner edge of the material segment 540. In one example, the outer edge of the material segment 540 can be formed concurrently with the edge of the upper electrode 515 in the same etch process so as to precisely define the edge of the BAW resonator 500.

Referring again to FIG. 8, the method may further include a step 850 of forming the mirror pair 740 over the upper electrode 720 (or 515). As discussed above, the mirror pair 740 may comprise the low acoustic impedance mirror layer 750 and a high acoustic impedance mirror layer 760. Accordingly, step 850 may include a step 860 of forming the low acoustic impedance mirror layer 750 and a step 870 of forming the high acoustic impedance mirror layer 760. The low acoustic impedance mirror layer 750 may be formed by depositing, using a suitable deposition process, and optionally patterning a layer of, for example, silicon dioxide. The high acoustic impedance mirror layer 760 may be formed, for example, using a suitable deposition or sputtering process, as discussed above with reference to steps 810 and 830, and optional patterning process. As discussed above, in one example, the high acoustic impedance mirror layer 760 is deposited more thickly in step 870 to allow a determined thickness to be removed in step 890 to thereby trim the resonant frequency of the resonator. In another example, frequency trimming may be performed on the low acoustic impedance mirror layer 750, which may therefore be deposited more thickly in step 860 to allow a determined thickness to be removed during step 890.

As discussed above, in one example, a cavity 790 may be formed between the substrate 770 and the vibrating part of the resonator. Accordingly, step 810 may include forming the lower electrode 730 on a sacrificial layer (not shown) which is subsequently removed in step 880 to create the cavity 790. Alternatively, the lower electrode and piezoelectric layer may be supported around its perimeter, for example, like a stretched membrane, as shown in FIG. 7B, and the cavity 702 may be realized by etching away the underlying portion of the substrate 770 in step 880, Thus, the method may optionally include a step 880 of forming the cavity, for example, by etching or otherwise removing either a portion of the substrate or a sacrificial layer, releasing the membranes (i.e., lower electrode and piezoelectric layer) and hence providing acoustic isolation for the resonator. The cavity 702 may be formed by a number of known methods, for example as described in U.S. Pat. No. 6,384,697 to Ruby, et al., referenced above. It is to be appreciated that step 880 may be performed earlier in the fabrication process, for example, after steps 820 or 830; however, it may be presently preferred or practical to form the cavity 702 just prior to the frequency trimming step 890.

The hybrid BAW structure according to various representative embodiments may provide significant improvements over known BAW resonator structures, including maintaining high coupling and good performance while providing significantly improved manufacturability, particularly at high frequencies. Having thus described several aspects of at least a representative embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. An acoustic wave resonator comprising:
(a) a substrate;
(b) a first electrode supported by the substrate;
(c) a piezoelectric layer formed on the first electrode;
(d) a second electrode formed on the piezoelectric layer;
(e) a pair of low and high impedance layers formed in contact with one of the first and second electrodes; and
(f) a passivation layer formed on the second electrode if the pair of low and high impedance layers is in contact with the first electrode, or on the pair of low and high impedance layers if the pair of low and high impedance layers is in contact with the second electrode.

2. The acoustic wave resonator of claim 1, wherein the substrate is provided with an air cavity or an acoustic mirror, whereby the first electrode is formed on the substrate and located over the air cavity or the acoustic mirror, and the pair of low and high impedance layers is in contact with the second electrode.

3. The acoustic wave resonator of claim 1, wherein the pair of low and high impedance layers comprises a low impedance layer and a high impedance layer.

4. An acoustic wave resonator comprising:
(a) a substrate;
(b) a first electrode supported by the substrate;
(c) a piezoelectric layer formed on the first electrode;
(d) a second electrode formed on the piezoelectric layer; and
(e) a passivation layer formed on the second electrode, wherein at least one of the first and second electrodes comprises a pair of low and high impedance layers.

5. The acoustic wave resonator of claim 4, wherein the substrate is provided with an air cavity or an acoustic mirror, whereby the first electrode comprises a metal electrode formed on the substrate and located over the air cavity or the acoustic mirror.

6. The acoustic wave resonator of claim 4, wherein the pair of low and high impedance layers comprises a low impedance layer and a high impedance layer.
